(19) United States
(12) Patent Application Publication
(10) Pub. No.: US 2026/0304628 A1
(43) Pub. Date: Oct. 1, 2026

(54) MULTIPHASE POWER MODULE WITH PAIRED POWER STAGES AND EMBEDDED INDUCTORS

(71) Applicant: Quanta Computer Inc., Taoyuan City (TW)

(72) Inventors: Kuo-Chan HSU, Taoyuan City (TW); Yun-Teng SHIH, Taoyuan City (TW); Chen-Jhen YANG, Taoyuan City (TW)

(21) Appl. No.: 19/253,656

(22) Filed: Jun. 27, 2025

Related U.S. Application Data
(60) Provisional application No. 63/779,939, filed on Mar. 28, 2025.

(51) Int. Cl. H05K 1/16; H05K 1/18; H05K 7/14

(52) U.S. Cl. CPC H05K 1/165; H05K 1/181; H05K 7/14322; H05K 2201/10015; H05K 2201/1003; H05K 2201/10522; H05K 2201/10545

(57) ABSTRACT

A power module for use in a computing device includes a printed circuit board (PCB) and a plurality of power stages mounted on the PCB. The PCB has a first surface and an opposing second surface. Each of the plurality of power stages is configured to receive an input voltage and to generate an output voltage used to power the load device. The plurality of power stages is arranged in one or more pairs of power stages. A first power stage of each pair of power stages is mounted on the first surface of the PCB. A second power stage of each pair of power stages is mounted on the opposing second surface of the PCB and aligned with the first power stage.

### CROSS-REFERENCE TO RELATED APPLICATIONS

This application claims the benefit of, and priority to, U.S. Provisional Patent Application No. 63/779,939 filed on Mar. 28, 2025, which is hereby incorporated by reference herein in its entirety.

### FIELD OF THE INVENTION

The present invention relates generally to a multiphase power module for providing power to a load within a computing device, and more specifically, to a multiphase power module having paired power stages and embedded inductors.

### BACKGROUND OF THE INVENTION

High-end servers and other computing devices may include multiple processing units and integrated circuits for performing complex tasks, such as central processing units (CPUs), graphics processing units (GPUs), application-specific integrated circuits (ASICs), and others. Such computing devices generally require a power module that can handle dynamic power requirements presented by the various processing units and integrated circuits. However, conventional power modules often have difficulty in responding to such dynamic conditions, resulting in uneven power delivery and uneven heat production within the power module, which can lead to thermal breakdown and damage. Thus, new power modules that are better able to respond to dynamic power conditions are needed.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to a first implementation of the present disclosure, a power module for use in powering a load device of a computing device is disclosed. The power module includes a printed circuit board (PCB) and a plurality of power stages mounted on the PCB. The PCB has a first surface and an opposing second surface. Each of the plurality of power stages is mounted on the PCB, and configured to receive an input voltage and to generate an output voltage used to power the load device. The plurality of power stages is arranged in one or more pairs of power stages. A first power stage of each pair of power stages is mounted on the first surface of the PCB. A second power stage of each pair of power stages is mounted on the opposing second surface of the PCB and aligned with the first power stage.

In some aspects of the first implementation, for each pair of power stages, a distance between the first power stage and the load device is substantially equal to a distance between the second power stage and the load device.

In some aspects of the first implementation, the load device is mounted on the first surface of the printed circuit board.

In some aspects of the first implementation, each of the plurality of power stages is configured to deliver the output voltage at a respective phase. For each pair of the plurality of power stages, the output voltage delivered by the first power stage is 180° out of phase with the output voltage delivered by the second power stage.

In some aspects of the first implementation, the plurality of power stages is formed in a plurality of power stage integrated circuits (ICs) that each include a first power stage of the plurality of power stages and a second power stage of the plurality of power stages. Each of the plurality of power stage ICs is mounted on the first surface of the PCB or the opposing second surface of the PCB.

In some aspects of the first implementation, the first power stage and the second power stage within each respective one of the plurality of power stage ICs are configured to deliver output voltages that are not 180° out of phase with each other.

In some aspects of the first implementation, the first power stage and the second power stage of each pair of power stages are located in separate ones of the plurality of power stage ICs.

In some aspects of the first implementation, each of the plurality of power stage ICs includes (i) one power stage of a first pair of the plurality of power stages, and (ii) one power stage of a second pair of the plurality of power stages that is different than the first pair of the plurality of power stages.

In some aspects of the first implementation, the plurality of power stages includes a first power stage and a second power stage formed in a first power stage IC; and a third power stage and a fourth power stage formed in a second power stage IC. The first power stage IC is mounted on the first surface of the PCB, and the second power stage IC is mounted on the opposing second surface of the PCB and aligned with the first power stage IC.

In some aspects of the first implementation, the first power stage and the third power stage are configured to deliver output voltages that are 180° out of phase with each other, and the second power stage and the fourth power stage are configured to deliver output voltages that are (i) 180° out of phase with each other and (ii) not 180° out of phase with the output voltages delivered by the first power stage and the third power stage.

In some aspects of the first implementation, (i) the first power stage is aligned on the first surface of the PCB with the third power stage on the opposing second surface of the PCB, and not with the fourth power stage, and (ii) the second power stage is aligned on the first surface of the PCB with the fourth power stage on the opposing second surface of the PCB, and not with the third power stage.

In some aspects of the first implementation, the plurality of power stages includes two power stages, and the one or more pairs of power stages includes one pair of power stages configured to deliver output voltages at about 0° and about 180°.

In some aspects of the first implementation, the plurality of power stages includes n power stages, and wherein the one or more pairs of power stages includes at least a first pair of power stages configured to deliver output voltages at about 0° and about 180°, and a second pair of power stages configured to deliver output voltages at about 0°+360°/n and about 180°+360°/n, where n is an even integer that is greater than or equal to 4.

In some aspects of the first implementation, the power module further includes at least one capacitor mounted on the first surface of the PCB and disposed within a recessed groove defined along a perimeter of the load device. The at least one capacitor is electrically connected to an output of at least one of the plurality of power stages.

In some aspects of the first implementation, the power module further includes a plurality of inductors, each of the plurality of inductors electrically connecting one of the plurality of power stages to the load device, each of the plurality of inductors including a winding formed from (i) one or more conductive traces of the PCB, (ii) one or more plated through-holes of the PCB, or (iii) any combination of (i) and (ii), wherein the winding of each of the plurality of inductors extends into an interior of the PCB between the first surface and the opposing second surface.

In some aspects of the first implementation, each of the plurality of inductors includes a core that is disposed at least partially within the interior of the PCB between the first surface and the opposing second surface, the winding of each of the plurality of inductors being wound around its core.

In some aspects of the first implementation, the plurality of power stages is formed in a plurality of power stage integrated circuits (ICs) that each include a first power stage of the plurality of power stages and a second power stage of the plurality of power stages, and wherein the two power stages of each power stage IC are electrically connected to inductors of the plurality of inductors that have separate windings wound around a shared core.

In some aspects of the first implementation, the shared core of each of the plurality of power stage ICs is electrically connected to a compensation inductor such that each of the plurality power stages and each of the plurality of inductors is electrically connected to the compensation inductor

In some aspects of the first implementation, the plurality of power stages is formed in a plurality of power stage integrated circuits (ICs) that each include two of the plurality of power stages, and wherein each of the power stage ICs has an area of about 6 millimeters by about 6 millimeters.

In some aspects of the first implementation, the load device includes one or more central processing units, one or more graphics processing units, or both.

According to a second implementation of the present disclosure, a computing device includes a housing, a load device disposed within the housing, and a power module disposed within the housing. The power module is configured to power the load device and includes a printed circuit board (PCB), and a plurality of power stages mounted on the PCB. The PCB has a first surface and an opposing second surface. Each of the plurality of power stages is configured to receive an input voltage and to generate an output voltage used to power the load device. The plurality of power stages is arranged in one or more pairs of power stages. A first power stage of each pair of power stages is mounted on the first surface of the PCB. A second power stage of each pair of power stages is mounted on the opposing second surface of the PCB and aligned with the first power stage.

In some aspects of the second implementation, for each pair of power stages, a distance between the first power stage and the load device is substantially equal to a distance between the second power stage and the load device.

In some aspects of the second implementation, each of the plurality of power stages is configured to deliver the output voltage at a respective phase, and for each pair of the plurality of power stages, the output voltage delivered by the first power stage is 180° out of phase with the output voltage delivered by the second power stage.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a pinout diagram of a power stage integrated circuit containing a first power stage and a second power stage, according to certain aspects of the present disclosure.

FIG. 2A is a top view of a power module that includes four of the power stage integrated circuits of FIG. 1, according to certain aspects of the present disclosure.

FIG. 2B is a bottom view of a power module of FIG. 2A, according to certain aspects of the present disclosure.

FIG. 3 is a side view of the power module of FIGS. 2A and 2B, according to certain aspects of the present disclosure.

FIG. 4A is a top view of a power module that includes four of the power stage integrated circuits of FIG. 1 and embedded inductors, according to certain aspects of the present disclosure.

FIG. 4B is a bottom view of a power module of FIG. 4A, according to certain aspects of the present disclosure.

FIG. 5 is a side view of the power module of FIGS. 2A and 2B, according to certain aspects of the present disclosure.

FIG. 6 is a perspective view of one of the embedded inductors of the power module of FIGS. 4A and 4B, according to certain aspects of the present disclosure.

FIG. 7 is a side view of a coupled inductor, according to aspects of the present disclosure.

### DETAILED DESCRIPTION

Various embodiments are described with reference to the attached figures, where like reference numerals are used throughout the figures to designate similar or equivalent elements. Each reference numeral identifies the figure in which the reference numeral first appears, based on the first digit (for three-digit reference numerals) or the first two digits (for four-digit reference numerals) corresponding to the figure numeral of the figure. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

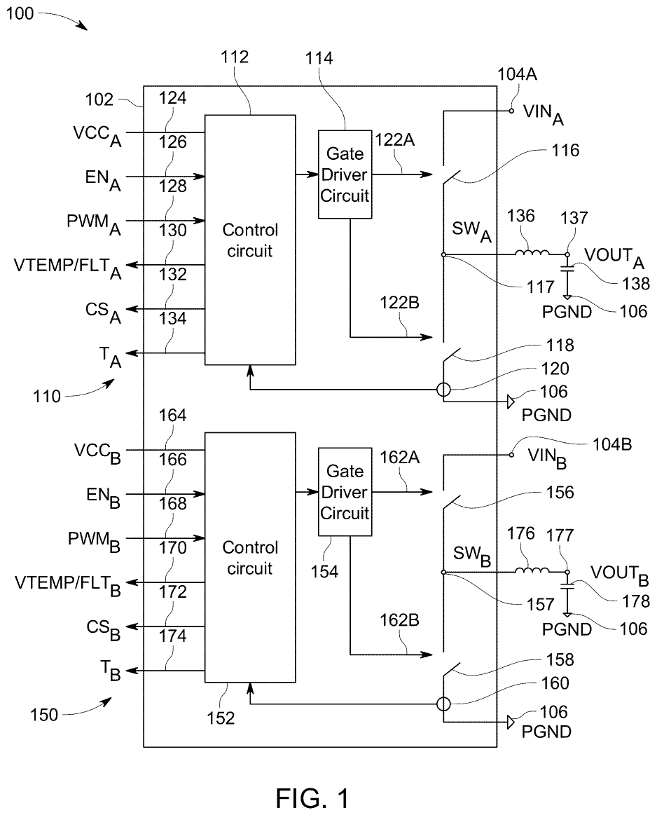

FIG. 1 is a pinout diagram of a power stage integrated circuit (IC) 100 showing the internal components thereof. The power stage IC 100 includes a first power stage 110 and a second power stage 150 housed within the package 102. Each of the power stages 110 and 150 is configured to receive an input voltage and generate an output voltage. In general, each of the power stages 110 and 150 converts an input voltage into a smaller output voltage, although in some cases the power stages 110 and 150 could step up the voltage or maintain the same voltage while performing other functions. In some implementations, the power stage IC 100 has an area of about 6 millimeters by about 6 millimeters.

The first power stage 110 includes a control circuit 112, a gate driver circuit 114, a high-side MOSFET 116, a low-side MOSFET 118, and a current sensor 120. The drain or source of the high-side MOSFET 116 is connected to a first input voltage 104A (labeled as VINA), and the other of the drain and the source is connected to the drain or source of the low-side MOSFET 118. The other of the drain and the source of the low-side MOSFET 118 is connected to ground 106 (labeled as PGND). During operation of the first power stage 110, the control circuit 112 and the gate driver circuit 114 alternatively open and close the high-side MOSFET 116 (via a first gate signal 122A) and the low-side MOSFET 118 (via a second gate signal 122B) such that a switched node 117 between the high-side MOSFET 116 and the low-side MOSFET 118 (labeled as SWA) is alternatively connected to the first input voltage 104A and the ground 106. The MOSFETs are operated so that when the high-side MOSFET 116 is closed and connected to the first input voltage 104A, the low-side MOSFET 118 is open and disconnected from the ground 106, and vice-versa. By opening and closing the MOSFETs 116 and 118 according to a specific duty cycle (for example via pulse width modulation, or PWM), a desired average voltage is produced at the switched node 117. This average voltage is the output voltage of the first power stage 110, and thus the switched node 117 acts as the output of the first power stage 110.

The control circuit 112 includes a number of inputs and outputs, including a power input 124 (labeled as VCCA), an enable input 126 (labeled as ENA), a pulse width modulation input 128 (labeled as PWMA), a fault output 130 (labeled as VTEMP/FLTA), a current sense output 132 (labeled as CSA), and a temperature output 134 (labeled as TA). The power input 124 receives an input voltage used to power the first power stage 110. The enable input 126 is configured to activate a functionality of the first power stage 110 when receiving the appropriate signal. The pulse width modulation input 128 is used to set the duty cycle of the switching the MOSFETS 116 and 118 (and thus to set the desired output voltage at the switched node 117). The fault output 130 will be pulled high or low if a fault is detected. The current sense output 132 is configured to output a signal indicative of the amount of current flowing through the low-side MOSFET 118 that is sensed by the current sensor 120. The temperature output 134 is a signal indicative of the temperature condition of the first power stage 110, and will be pulsed high or low if a temperature fault is detected.

The second power stage 150 is generally identical to the first power stage 110, and includes a control circuit 152, a gate driver circuit 154, a high-side MOSFET 156, a low-side MOSFET 158, and a current sensor 160. The drain or source of the high-side MOSFET 156 is connected to a second input voltage 104B (labeled as VINB), and the other of the drain and the source is connected to the drain or source of the low-side MOSFET 158. The other of the drain and the source of the low-side MOSFET 158 is connected to ground 106 (labeled as PGND). In some implementations, both the first power stage 110 and the second power stage 150 receive the same input voltage, and thus the second input voltage 104B may be the same voltage source as the first input voltage 104A. In other implementations, the input voltages 104A and 104B may be from different voltage sources.

During operation of the second power stage 150, the control circuit 152 and the gate driver circuit 154 alternatively open and close the high-side MOSFET 156 (via a first gate signal 162A) and the low-side MOSFET 158 (via a second gate signal 162B) such that a switched node 157 between the high-side MOSFET 156 and the low-side MOSFET 158 (labeled as SWB) is alternatively connected to the second input voltage 104B and the ground 106. The MOSFETs are operated so that when the high-side MOSFET 156 is closed and connected to the second input voltage 104B, the low-side MOSFET 158 is open and disconnected from the ground 106, and vice-versa. By opening and closing the MOSFETs 156 and 158 according to a specific duty cycle (for example via pulse width modulation, or PWM), a desired average voltage is produced at the switched node 157. This average voltage is the output voltage of the second power stage 150, and thus the switched node 157 acts as the output of the second power stage 150.

The control circuit 152 includes generally the same inputs and outputs as the control circuit 112, including a power input 164 (labeled as VCCB), an enable input 166 (labeled as ENB), a pulse width modulation input 168 (labeled as PWMB), a fault output 170 (labeled as VTEMP/FLTB), a current sense output 172 (labeled as CSB), and a temperature output 174 (labeled as TB). The power input 164 receives an input voltage used to power the second power stage 150 (which may be from the same voltage source as the input voltage received at the power input 124 or a different voltage source). The enable input 166 is configured to activate a functionality of the second power stage 150 when receiving the appropriate signal. The pulse width modulation input 168 is used to set the duty cycle of the switching the MOSFETS 156 and 158 (and thus to set the desired output voltage at the switched node 157). The fault output 170 will be pulled high or low if a fault is detected. The current sense output 172 is configured to output a signal indicative of the amount of current flowing through the low-side MOSFET 158 that is sensed by the current sensor 160. The temperature output 174 is a signal indicative of the temperature condition of the second power stage 150, and will be pulsed high or low if a temperature fault is detected.

Also shown in FIG. 1 are the inductors 136, 176 and capacitors 138, 178 used to filter the output voltages at the switched nodes 117 and 157 so as to generate a smooth final voltage that can be provided to a load device (e.g., a CPU, a GPU, etc.). These inductors are generally not part of the power stage IC 100 itself (e.g., are not housed within the packaging of the power stage IC 100), but in some cases may be.

One end of the inductor 136 is electrically connected to the switched node 117 between the high-side MOSFET 116 and the low-side MOSFET 118, and the other end of the inductor 136 is connected to the capacitor 138. The other end of the capacitor 138 is connected to the ground 106. A final voltage is produced at a final voltage node 137 (labeled as VOUTA) between the inductor 136 and the capacitor 138. This final voltage is the ultimate voltage from the first power stage 110 that can be delivered to the load device.

Similarly, one end of the inductor 176 is electrically connected to the switched node 157 between the high-side MOSFET 156 and the low-side MOSFET 158, and the other end of the inductor 176 is connected to the capacitor 178. The other end of the capacitor 178 is connected to the ground 106. A final voltage is produced at a final voltage node 177 (labeled as VOUTB) between the inductor 176 and the capacitor 178. This final voltage is the ultimate voltage from the second power stage 150 that can be delivered to the load device.

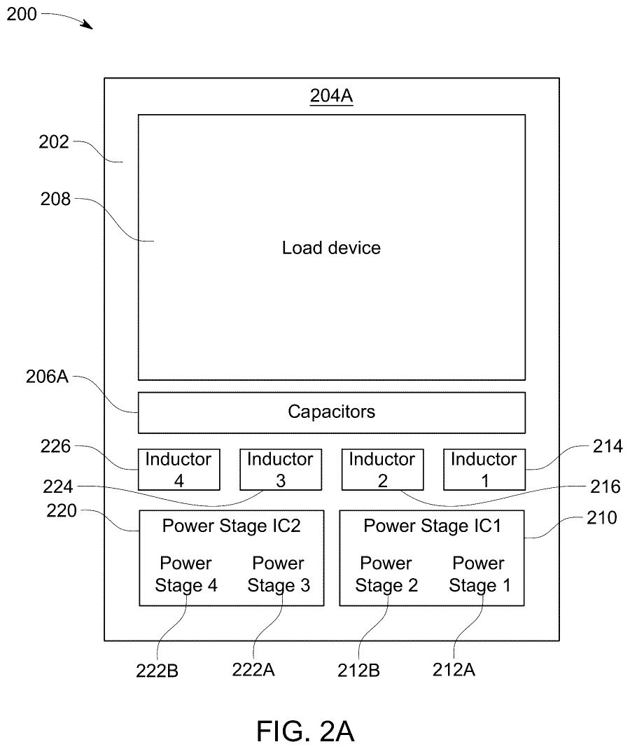

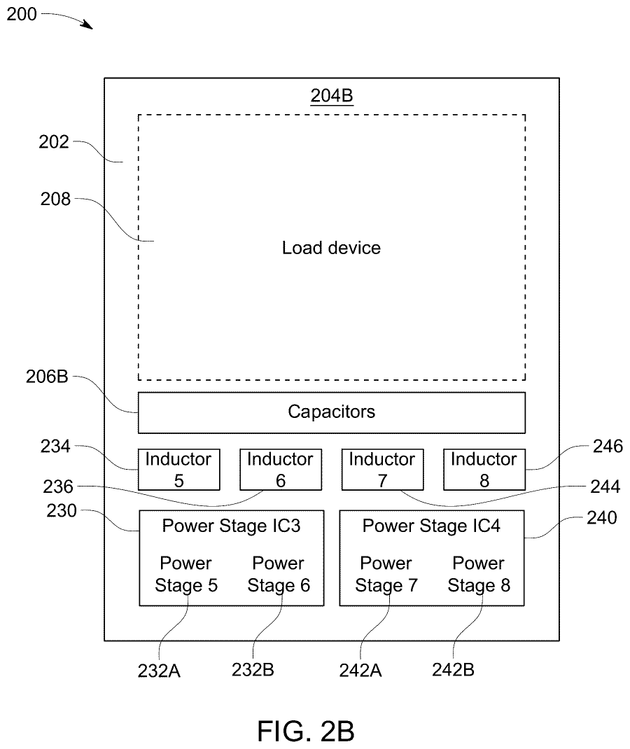

FIG. 2A is a block diagram representation of a top view of a power module 200 that includes a plurality of power stages that are formed from a plurality of the power stage ICs 100. FIG. 2B is a block diagram representation of a bottom view of the power module 200. The power module 200 is generally a component of a computing device and/or system that receives and manages power for various components of the computing device and/or system. The power module 200 may receive power generally directly from mains electricity, or may receive power via an intermediary device, such as a power rail of a rack-mount system. In some cases, the power module 200 may be referred to as a high power module.

As shown, the power module 200 includes a printed circuit board (PCB) 202 on which various different components are mounted. The power module 200 includes a first power stage IC 210 and a second power stage IC 220 mounted on a first (e.g., top) surface 204A of the PCB 202, and a third power stage IC 230 and a fourth power stage IC 240 mounted on an opposing second (e.g., bottom) surface 204B of the PCB 202. Each of the power stage ICs 210-240 is generally the same as or similar to the power stage IC 100 of FIG. 1, and includes two separate power stages, each of which is the same as or similar to the first power stage 110 and the second power stage 150. The first power stage IC 210 includes a first power stage 212A and a second power stage 212B. The second power stage IC 220 includes a first power stage 222A (third power stage overall) and a second power stage 222B (fourth power stage overall). The third power stage IC 230 includes a first power stage 232A (fifth power stage overall) and a second power stage 232B (sixth power stage overall). The fourth power stage IC 240 includes a first power stage 242A (seventh power stage overall) and a second power stage 242B (eighth power stage overall).

Each of these power stages is configured to provide a voltage at its switched node that is electrically connected to a corresponding inductor. Inductors 214 and 216 are mounted on the top surface 204A of the PCB 202 adjacent to the first power stage IC 210, and are electrically connected to the switched nodes of the first power stage 212A and the second power stage 212B, respectively. Inductors 224 and 226 are mounted on the top surface 204A of the PCB 202 adjacent to the second power stage IC 220, and are electrically connected to the switched nodes of the first power stage 222A and the second power stage 222B, respectively. Inductors 234 and 236 are mounted on the bottom surface 204B of the PCB 202 adjacent to the third power stage IC 230, and are electrically connected to the switched nodes of the first power stage 232A and the second power stage 232B, respectively. Inductors 244 and 246 are mounted on the bottom surface 204B of the PCB 202 and are electrically connected to the switched nodes of the first power stage 242A and the second power stage 242B, respectively.

The inductors 214-246 are electrically connected to capacitors, similar to what is shown in FIG. 1. In FIGS. 2A and 2B, the capacitors are shown as a single set of capacitors 206A mounted on the top surface 204A, and a single set of capacitors 206B mounted on the bottom surface 204B. In some implementations, the inductors 214, 216, 224, and 226 are electrically connected to the set of capacitors 206A, and the inductors 234, 236, 244, and 246 are electrically connected to the set of capacitors 206B. In other implementations however, each of the inductors 214-246 is connected to its own set of one or more capacitors. In any implementation, the load device 208, which is mounted on the top surface 204A of the PCB 202, is connected between the inductors 214-246 and the capacitors 206A and 206B.

Separate from the arrangement of two of the power stages 212A-242B within each power stage IC 210-240, the plurality of power stages 212A-242B are arranged in pairs of power stages on opposite surfaces of the PCB 202. Each pair of power stages includes one power stage mounted on the top surface 204A of the PCB 202, and another power stage mounted on the bottom surface 204B of the PCB 202. The pairs of power stages are aligned so that within each pair of power stages, the distance between each of the power stages and the load device 208 is substantially equal. The distances are generally the same except for the thickness of the PCB 202, which is generally negligible.

To achieve the alignment on opposite surfaces of the PCB 202 for each pair of power stages, the power stage ICs 210-240 are also aligned. As shown, the first power stage IC 210 is mounted on the top surface 204A, and the third power stage IC 230 is mounted on the bottom surface 204B aligned with the first power stage IC 210. Similarly, the second power stage IC 220 is mounted on the top surface 204A, and the fourth power stage IC 240 is mounted on the bottom surface 204B aligned with the second power stage IC 220. The alignment of the power stage ICs 210-240 results in each of the designated pairs of power stages 212A-242B being aligned.

Each power stage within each power stage IC is aligned with only one of the power stages of one of the other power stage ICs. Within the aligned power stage ICs 210 and 230, the first power stage 212A of the first power stage IC 210 is aligned with first power stage 232A of the third power stage IC 230 but not with the second power stage 232B. The second power stage 212B of the first power stage IC 210 is aligned with second power stage 232B of the third power stage IC 230 but not with the first power stage 232A. Similarly, within the aligned power stage ICs 220 and 240, the first power stage 222A of the second power stage IC 220 is aligned with first power stage 242A of the fourth power stage IC 240 but not with the second power stage 242B. The second power stage 222B of the second power stage IC 220 is aligned with second power stage 242B of the fourth power stage IC 240 but not with the first power stage 242A.

The power module 200 is a multiphase power module, where the output voltage generated by each of the individual power stage has a ripple component (sometimes referred to as the output ripple voltage) with its own phase. The power stage ICs 210-240 are arranged so that the two output voltages generated at the switched nodes of the power stages within each pair of power stages are 180° out of phase with each other. Because the pair of power stages are substantially the same distance from the load device 208 (the thickness of the PCB 202 being negligible), the voltages at the load device 208 from the pair of power stages remain about 180° out of phase with each other.

Thus, in the illustrated implementation, the following pairs of power stages 212A-242B generate output voltages that are 180° out of phase with each other: (i) the first power stage 212A of the first power stage IC 210 and the first power stage 232A of the third power stage IC 230; (ii) the second power stage 212B of the first power stage IC 210 and the second power stage 232B of the third power stage IC 230; (iii) the first power stage 222A of the second power stage IC 220 and the first power stage 242A of the fourth power stage IC 240; and (iv) the second power stage 222B of the second power stage IC 220 and the second power stage 242B of the fourth power stage IC 240.

In one example of this implementation, the phases of the output voltages are evenly distributed. Thus, a first pair of power stages has output voltages at about 0° and about 180; a second pair of the power stages has output voltages at about 45° and about 225°; a third pair of the power stages has output voltages at about 90° and about 270°; and a fourth pair of power stages has output voltages at about 135° and about 315°.

Other implementations can have different numbers of power stages and/or power stage ICs while still having the power stages arranged in pairs of power stages with a 180° phase difference in the voltage. For example, a power module could have ten power stages with output voltage pairs of: 0° and 180°; 36° and 216°; 72° and 252°; 108° and 288°; and 144° and 324°. In another example, a power module could have twelve power stages with output voltage pairs of 0° and 180°; 30° and 210°; 60° and 240°; 90° and 270°; 120° and 300°; and 150° and 330°.

In general, if a multiphase power module has n power stages where n is an even integer greater than or equal to 4, then the power module will include at least a first pair of power stages with output voltages at 0° and 180°. Subsequent pairs of power stages will have output voltages that are integer multiples of

$$0 ° + \frac{360 °}{n} and 180 ° + \frac{360 °}{n} .$$

The m^{th} pair of power stages, where m is an even integer that is less than or equal to n/2, will have output voltages of

$$0 ° + \frac{360 ° \times ( m - 1 )}{n} and 180 ° + \frac{360 ° \times ( m - 1 )}{n} .$$

Implementations according to the present disclosure can have any number of power stages, so long as the two power stages in each pair are substantially the same distance away from the load device 208, and/or generate output voltages that are 180° out of phase with each other. In general the two power stages in each pair will be aligned on opposite surfaces of the PCB 202, but in some cases, the two power stages in each pair could be mounted on the same surface of the PCB 202. Further, details of the present disclosure are generally applicable to power modules where the output voltages have any degree of oscillating component, whether the output voltages are specifically designed as AC voltages, or whether the output voltages are designed as DC voltages and have a small oscillating (or ripple) component.

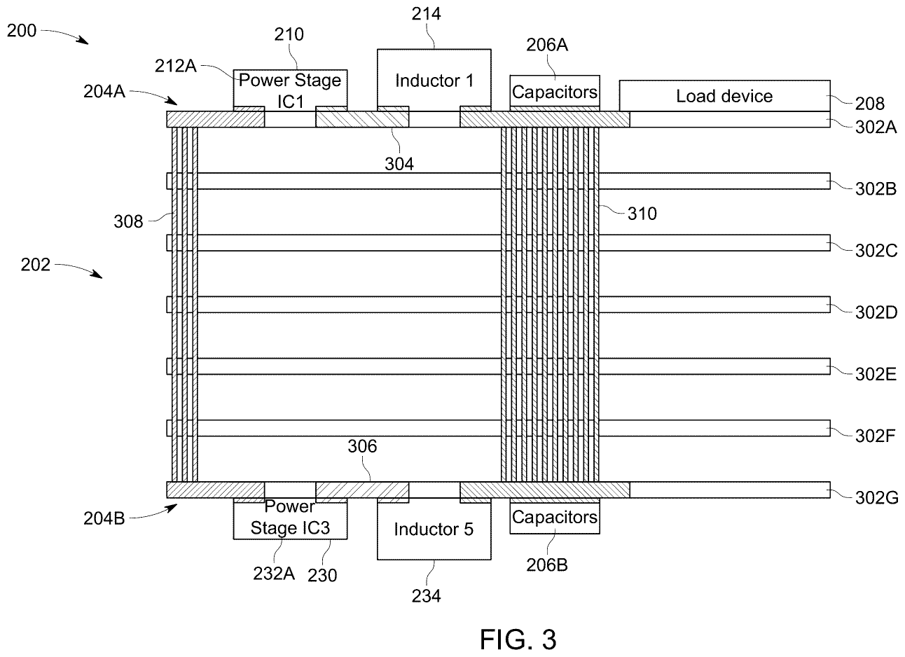

FIG. 3 shows a partially exploded side view of the power module 200 from the side nearest the first power stage IC 210 and the third power stage IC 230. As shown, the PCB 202 is formed from a plurality of layers 302A-302G. The first power stage IC 210, the inductor 214, the set of capacitors 206A, and the load device 208 are mounted on the top surface 204A. The third power stage IC 230, the inductor 234, and the set of capacitors 206B are mounted on the bottom surface 204B. The PCB 202 includes an electrical trace 304 formed on and/or in the top layer 302A that electrically connects the first power stage IC 210 (i.e., the first power stage 212A of the first power stage IC 210) to the inductor 214. Similarly, the PCB 202 includes an electrical trace 306 formed on and/or in the bottom layer 302G that electrically connects the third power stage IC 230 (i.e., the first power stage 232A of the third power stage IC 230) to the inductor 234.

The PCB also includes a series of electrical connections 308 formed as plated through-holes and/or conductive traces on and/or in the PCB layers 302A-302G that electrically connect the first power stage IC 210 and the third power stage IC 230. These electrical connections 308 can be used for inputs that may be common to both the power stage ICs 210 and 230 (as well as the other power stage ICs 220 and 240 that are not visible in FIG. 3), such as the power inputs (e.g., the power inputs 124 and 164 of FIG. 1), the enable inputs (e.g., the enable inputs 126 and 166 of FIG. 1), the pulse width modulation inputs (e.g., the pulse width modulation inputs 128 and 168 of FIG. 1), and any other common inputs. The electrical connections 308 may also be used for any outputs that can be shared between the power stage ICs, such as the temperature/fault output (e.g., the temperature/fault outputs 130 and 170 of FIG. 1). Finally, the PCB includes another series of electrical connections 310 formed as plated through-holes and/or conductive traces on and/or in the PCB layers 302A-302G that are used to electrically connect the inductors 214 and 234 (as well as the other inductors not visible in FIG. 3) to the sets of capacitors 206A and 206B, and the load device 208.

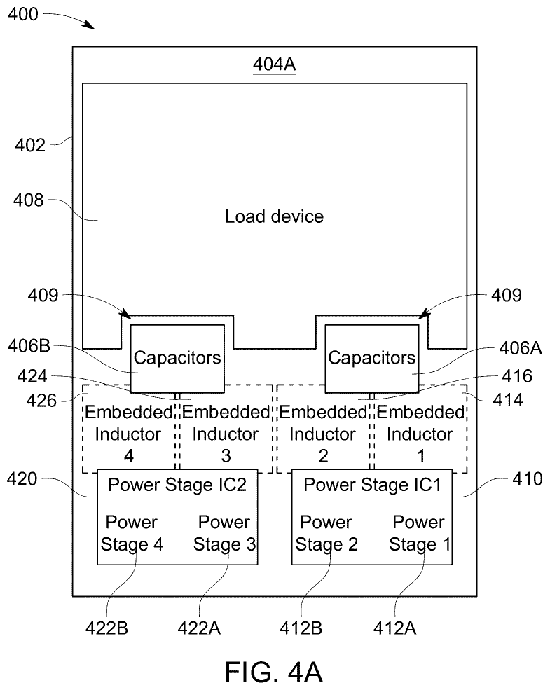

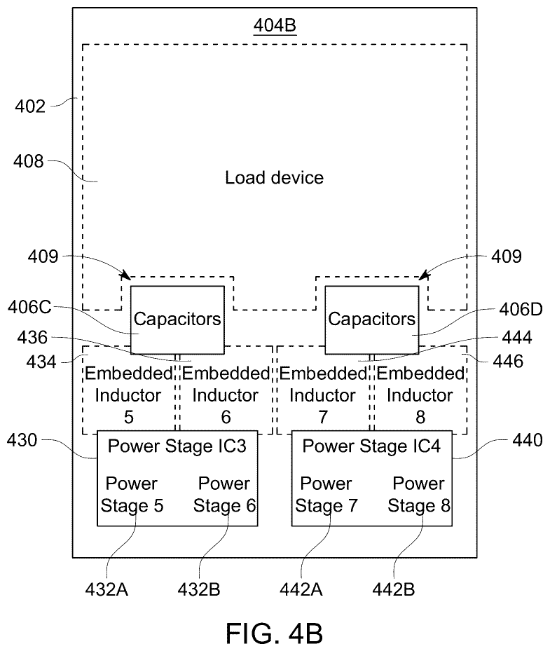

FIG. 4A is a block diagram representation of a top view of a power module 400 that is similar to the power module 200 of FIGS. 2A and 2B. FIG. 4B is a block diagram representation of a bottom view of the power module 400. The power module 400 includes a PCB 402, first and second power stage ICs 410 and 420 mounted on a top surface 404A of the PCB 402, and third and fourth power stage ICs 430 and 440 mounted on an opposing bottom surface 404B of the PCB 402. The first power stage IC 410 is aligned on the top surface 404A with the third power stage IC 430 on the bottom surface 404B, and the second power stage IC 420 is aligned on the top surface 404A with the fourth power stage IC 440 on the bottom surface 404B. The power module 400 also includes two sets of capacitors 406A and 406B mounted on the top surface 404A, and two sets of capacitors 406C and 406D mounted on the bottom surface 404B.

The power stages within the power stage ICs are formed in pairs that generate output voltages that have a phase difference of 180°. The first power stage 412A of the first power stage IC 410 is aligned with the first power stage 432A of the third power stage IC 430. The second power stage 412B of the first power stage IC 410 is aligned with the second power stage 432B of the third power stage IC 430. The first power stage 422A of the second power stage IC 420 is aligned with the first power stage 442A of the fourth power stage IC 440. The second power stage 422B of the second power stage IC 420 is aligned with the second power stage 442B of the fourth power stage IC 440.

Power module 400 has two main differences from power module 200 in FIG. 2. First, the power module 400 includes embedded inductors that are formed within the layers of the PCB 402, instead of being separate components mounted on the top and bottom surfaces of the PCB 402. As shown in FIG. 4A and FIG. 4B, the embedded inductors include eight separate embedded inductors 414, 416, 424, 426, 434, 436, 444, and 446 that are electrically connected to the power stages 412A-442B, respectively. Each of the embedded inductors includes a core that is disposed partially or entirely within the layers of the PCB 402, and a winding that is formed from any combination of plated through-holes extending through the different layers of the PCB 402, and conductive traces formed along the different layers of the PCB 402. Thus, the winding of each embedded inductor 414-446 extends into the interior of the PCB 402 between the top surface 404A and the opposing bottom surface 404B. Because the inductors 414-446 are embedded within the PCB 402 instead of being mounted on the top surface 404A of the PCB 402, the power stage ICs 410-440 are able to be mounted closer to the inductors 414-446, the sets of capacitors 406A-406D, and the load device 408.

Second, the load device 408 has a number of recessed grooves 409 defined along the perimeter thereof into which the capacitors 406A-406D can be positioned. This allows the capacitors 406A-406D to be positioned closer to the load device 408, which in turn also enables the power stage ICs 410-440 to be positioned closer to the load device 408. Positioning the power stage ICs 410-440 closer to the load device 408 enables faster and more accurate operation of the power stages 412A-444B (e.g., in response to changing conditions of the load device 408).

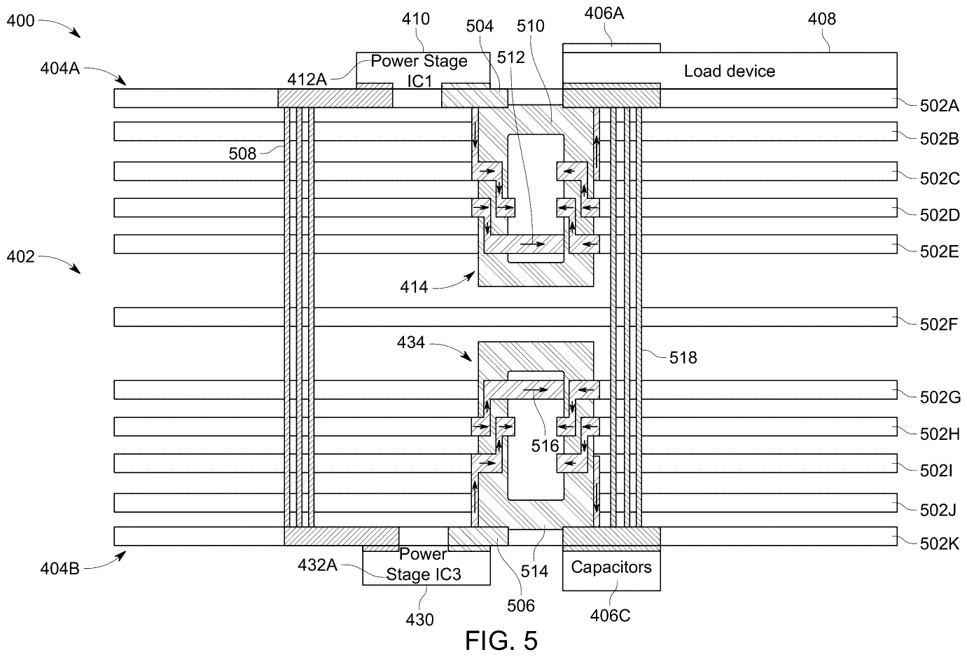

FIG. 5 shows a partially exploded side view of the power module 400 from the side nearest the first power stage IC 410 and the third power stage IC 430, similar to the view of the power module 200 shown in FIG. 3. As shown, the PCB 402 is formed from a plurality of layers 502A-502K. The first power stage IC 410, the set of capacitors 406A, and the load device 408 are mounted on the top surface 404A. The third power stage IC 430 and the set of capacitors 406C are mounted on the bottom surface 404B. As can be seen in FIG. 5, the sets of capacitors 406A and 406B (not visible in FIG. 5) are positioned within the recessed grooves 409 (FIG. 4A) of the load device 408 and thus overlap with the load device 408 from the perspective of the view shown in FIG. 5.

The PCB 402 includes an electrical trace 504 formed on and/or in the top layer 502A that is electrically connected to the first power stage IC 410 (i.e., the first power stage 412A of the first power stage IC 410). Similarly, the PCB 402 includes an electrical trace 506 formed on and/or in the bottom layer 502K that is electrically connected to the third power stage IC 430 (i.e., the first power stage 432A of the third power stage IC 430).

The PCB 402 also includes a series of electrical connections 508 formed as plated through-holes and/or conductive traces on and/or in the PCB layers 502A-502K that electrically connect the first power stage IC 410 and the third power stage IC 430. Similar to PCB 202 and electrical connections 308, the electrical connections 508 can be used for inputs and/or outputs that may be common to both the power stage ICs 410 and 430 (as well as the other power stage ICs 420 and 440 that are not visible in FIG. 5).

However, instead of having the electrical traces 504 and 506 electrically connect the power stage ICs 410 and 430 to surface-mount inductors, the electrical traces 504 and 506 instead electrically connect to embedded inductors 414 and 434 that are formed within the layers 502A-502K of the PCB 402. As shown, embedded inductor 414 is formed from a core 510 that extends within layers 502B-502E, and a winding 512 that extends between and along layers 502B-502E. Similarly, embedded inductor 434 is formed from a core 514 that extends within layers 502G-502J, and a winding 516 that extends between and along layers 502G-502J. The windings 512 and 516 can be formed by any combination of plated through-holes that extend between any one or more of the layers 502A-502K, and conductive traces that extend between and/or along any one or more of the layers 502A-502K. While FIG. 5 shows the embedded inductor 414 being formed only in the top half of the layers 502A-502K and the embedded inductor 434 being formed only in the bottom half of the layers 502A-502K, any embedded inductors can generally be formed in any of the layers of the PCB 402, including more than half of the layers.

Finally, the PCB 402 includes another series of electrical connections 518 formed as plated through-holes and/or conductive traces on and/or in the PCB layers 502A-502K that are used to electrically connect the sets of capacitors 406A and 406C, the load device 408, and the embedded inductors 414 and 434. Unlike the electrical connections 310 on PCB 202 (FIG. 3) however, the electrical connections 518 electrically connect to the windings 512 and 516 within the layers 502A-502K of the PCB 402, instead of connecting to surface-mount inductors on the top surface 404A of the PCB 402.

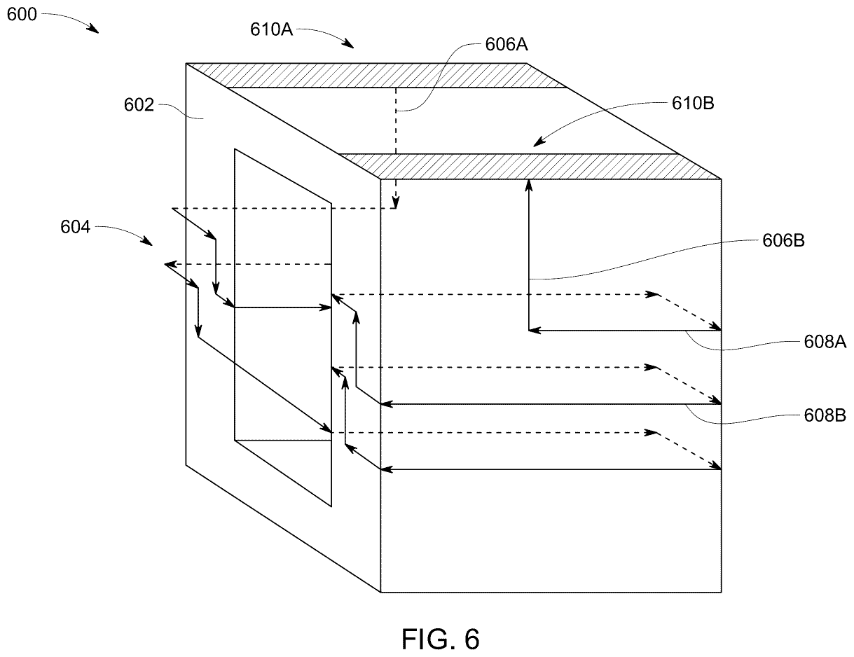

FIG. 6 shows a perspective view of an embedded inductor 600, which is an example of any of the embedded inductors 414-446 (FIG. 4). As shown, the embedded inductor 600 includes a core 602 and a winding 604 that is wound around the core 602. The winding 604 may be formed from plated through-holes that extend between layers of the PCB (such as vertical portions 606A and 606B), and from conductive traces that extend along layers of the PCB (such as horizontal portions 608A and 608B). However, while the embedded inductor 600 is shown in FIG. 6 as having distinct vertical and horizontal portions, the windings of embedded inductors according to the present disclosure may have generally any shape so long as they are wound around a core formed at least partially within the layers of the PCB. As shown in FIG. 6, the winding 604 can terminate in surface portions 610A and 610B, which may be electrically conductive portions of the top surface 404A of the PCB 402 and/or the bottom surface 404B of the PCB 402, and can be used to electrically connect the inductor 600 to other components (e.g., to any of the power stage ICs 410-440, to any of the sets of capacitors 406A-406D, to the load device 408, etc.).

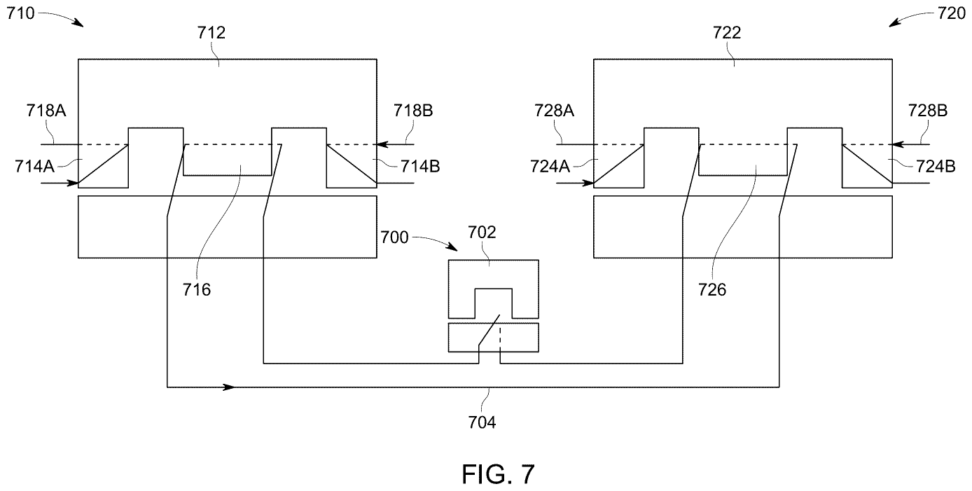

FIG. 7 shows hybrid coupled inductors 710 and 720 that can be used in the power module 200. Each of the hybrid coupled inductors can replace any pair of the inductors 416-446 in the power module 400 (FIGS. 4A, 4B, and 5). The inductor 710 includes a core portion 712 that forms two outer teeth 714A and 714B, and an inner tooth 716. Winding 718A is wound around outer tooth 714A, and winding 718B is wound around outer tooth 714B. Tooth 714A and winding 718A form the inductor for one of the power stages of the power module 200 and/or the power module 400, and tooth 714B and winding 718B form the inductor for another of the power stages of the power module 200 and/or the power module 400. The inductor 710 can generally be formed as an embedded inductor for use with the power module 400, but may also be formed as a surface mount inductor in some cases.

The inductor 720 is substantially identical to inductor 710, and includes a core portion 722 that forms two outer teeth 724A and 724B, and an inner tooth 726. Winding 728A is wound around outer tooth 724A, and winding 728B is wound around outer tooth 724B. Tooth 724A and winding 728A form the inductor for one of the power stages of the power module 400, and tooth 724B and winding 728B form the inductor for another of the power stages of the power module 400. The inductor 720 can generally be formed as an embedded inductor for use with the power module 400, but may also be formed as a surface mount inductor in some cases.

The hybrid coupled inductors 710 and 720 each further connected to a compensation inductor 700, which is formed from a core 702 and a winding 704. The winding 704 is wound around the core 702 of the compensation inductor 700, as well as the inner tooth 716 of the inductor 710, and the inner tooth 726 of the inductor 720. This compensation inductor 700 couples the inductors 710 and 720 together, which in turn allows for a faster transient response. When the output voltage of the power stages is perturbed by changing load requirements, the compensation inductor 700 assists in enhancing the compensation among the power stages coupled together via the coupled inductors 710 and 720, thereby strengthening the response of the power stages to the variable conditions.

The two power stages that share a given one of the inductors 710 and 720 can include two power stages in the same power stage IC, such as the first power stage 412A and the second power stage 412B of the first power stage IC 410 (FIG. 4A). The two power stages that share a given one of the inductors 710 and 720 could also include two power stages that are not in the same power stage IC, and are not paired together (e.g., do not generate output ripple voltages that have a phase difference of 180°), such as the first power stage 412A of the first power stage IC 410 and the first power stage 422A of the second power stage IC 420 (FIG. 4A). In some cases, the two power stages that share a given one of the inductors 710 and 720 may also be two inductors on opposite sides of the PCB.

While FIG. 7 illustrates only two hybrid coupled inductors 710 and 720, implementations according to the present disclosure could include any number of hybrid coupled inductors. In implementations having more than the two hybrid coupled inductors 710 and 720, additional hybrid coupled inductors will also be coupled to the compensation inductor 700. In some cases, a single winding is wound around the compensation inductor 700 and the inner tooth of each of the hybrid coupled inductors. In other cases, each of the hybrid coupled inductors has its own winding that is wound around its own inner tooth and the compensation inductor 700. In this manner, each of the power stages and each of the corresponding inductors can be electrically connected to the compensation inductor.

The power module 400 includes eight separate embedded inductors 414-446, and thus implementations of the power module utilizing hybrid coupled inductors could include four separate embedded inductor cores, each core forming two of the embedded inductors 414-446. In an example of this implementation, a first hybrid coupled inductor forms the inductor 414 and the inductor 416; a second hybrid coupled inductor forms the inductor 424 and the inductor 426; a third hybrid coupled inductor forms the inductor 434 and the inductor 436; and a fourth hybrid coupled inductor forms the inductor 444 and the inductor 446. Moreover, while the hybrid coupled inductors 710 and 720 and the compensation inductor 700 are described herein with reference to the power module 400 and the embedded inductors 414-446, such hybrid coupled inductors may also be used to form the surface-mount inductors 214-246 of the power module 200 (FIGS. 2A and 2B). In such implementations, the same principles generally apply, and each hybrid coupled inductor may be shared by two power stages in the same power stage IC, or two power stages that are not in the same power stage IC and are not paired together.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A power module for use in powering a load device of a computing device, the power module comprising:
a printed circuit board (PCB) having a first surface and an opposing second surface; and
a plurality of power stages mounted on the PCB, each of the plurality of power stages being configured to receive an input voltage and to generate an output voltage used to power the load device,
wherein the plurality of power stages is arranged in one or more pairs of power stages, a first power stage of each pair of power stages being mounted on the first surface of the PCB, and a second power stage of each pair of power stages being mounted on the opposing second surface of the PCB and aligned with the first power stage.

2. The power module of claim 1, wherein for each pair of power stages, a distance between the first power stage and the load device is substantially equal to a distance between the second power stage and the load device.

3. The power module of claim 2, wherein the load device is mounted on the first surface of the printed circuit board.

4. The power module of claim 1, wherein each of the plurality of power stages is configured to deliver the output voltage at a respective phase, and wherein for each pair of the plurality of power stages, the output voltage delivered by the first power stage is 180° out of phase with the output voltage delivered by the second power stage.

5. The power module of claim 4, wherein the plurality of power stages is formed in a plurality of power stage integrated circuits (ICs) that each include a first power stage of the plurality of power stages and a second power stage of the plurality of power stages, each of the plurality of power stage ICs being mounted on the first surface of the PCB or the opposing second surface of the PCB.

6. The power module of claim 5, wherein the first power stage and the second power stage within each respective one of the plurality of power stage ICs are configured to deliver output voltages that are not 180° out of phase with each other.

7. The power module of claim 5, wherein the first power stage and the second power stage of each pair of power stages are located in separate ones of the plurality of power stage ICs.

8. The power module of claim 5, wherein each of the plurality of power stage ICs includes (i) one power stage of a first pair of the plurality of power stages, and (ii) one power stage of a second pair of the plurality of power stages that is different than the first pair of the plurality of power stages.

9. The power module of claim 5, wherein the plurality of power stages includes a first power stage and a second power stage formed in a first power stage IC, and a third power stage and a fourth power stage formed in a second power stage IC, the first power stage IC being mounted on the first surface of the PCB, the second power stage IC being mounted on the opposing second surface of the PCB and aligned with the first power stage IC.

10. The power module of claim 9, wherein the first power stage and the third power stage are configured to deliver output voltages that are 180° out of phase with each other, and wherein the second power stage and the fourth power stage are configured to deliver output voltages that are (i) 180° out of phase with each other and (ii) not 180° out of phase with the output voltages delivered by the first power stage and the third power stage.

11. The power module of claim 10, wherein (i) the first power stage is aligned on the first surface of the PCB with the third power stage on the opposing second surface of the PCB, and not with the fourth power stage, and (ii) the second power stage is aligned on the first surface of the PCB with the fourth power stage on the opposing second surface of the PCB, and not with the third power stage.

12. The power module of claim 5, wherein the plurality of power stages includes n power stages, and wherein the one or more pairs of power stages includes at least a first pair of power stages configured to deliver output voltages at about 0° and about 180°, and a second pair of power stages configured to deliver output voltages at about
$$0 ° + \frac{360 °}{n}$$
and about
$$180 ° + \frac{360 °}{n} ,$$
where n is an even integer that is greater than or equal to 4.

13. The power module of claim 1, further comprising at least one capacitor mounted on the first surface of the PCB and disposed within a recessed groove defined along a perimeter of the load device, the at least one capacitor being electrically connected to an output of at least one of the plurality of power stages.

14. The power module of claim 1, further comprising a plurality of inductors, each of the plurality of inductors electrically connecting one of the plurality of power stages to the load device, each of the plurality of inductors including a winding formed from (i) one or more conductive traces of the PCB, (ii) one or more plated through-holes of the PCB, or (iii) any combination of (i) and (ii), wherein the winding of each of the plurality of inductors extends into an interior of the PCB between the first surface and the opposing second surface.

15. The power module of claim 14, wherein each of the plurality of inductors includes a core that is disposed at least partially within the interior of the PCB between the first surface and the opposing second surface, the winding of each of the plurality of inductors being wound around its core.

16. The power module of claim 15, wherein the plurality of power stages is formed in a plurality of power stage integrated circuits (ICs) that each include a first power stage of the plurality of power stages and a second power stage of the plurality of power stages, and wherein the two power stages of each power stage IC are electrically connected to inductors of the plurality of inductors that have separate windings wound around a shared core.

17. The power module of claim 16, wherein the shared core of each of the plurality of power stage ICs is electrically connected to a compensation inductor such that each of the plurality power stages and each of the plurality of inductors is electrically connected to the compensation inductor.

18. A computing device comprising:
a housing;
a load device disposed within the housing; and
a power module disposed within the housing, the power module being configured to power the load device and including:
a printed circuit board (PCB) having a first surface and an opposing second surface; and
a plurality of power stages mounted on the PCB, each of the plurality of power stages being configured to receive an input voltage and to generate an output voltage used to power the load device,
wherein the plurality of power stages is arranged in one or more pairs of power stages, a first power stage of each pair of power stages being mounted on the first surface of the PCB, and a second power stage of each pair of power stages being mounted on the opposing second surface of the PCB and aligned with the first power stage.

19. The computing device of claim 18, wherein for each pair of power stages, a distance between the first power stage and the load device is substantially equal to a distance between the second power stage and the load device.

20. The computing device of claim 18, wherein each of the plurality of power stages is configured to deliver the output voltage at a respective phase, and wherein for each pair of the plurality of power stages, the output voltage delivered by the first power stage is 180° out of phase with the output voltage delivered by the second power stage.
